(19) United States
(12) Patent Application Publication
(10) Pub. No.: US 2024/0081058 A1
(43) Pub. Date: Mar. 7, 2024

(54) MEMORY DEVICE AND METHOD OF FABRICATING THE SAME

(71) Applicant: MACRONIX International Co., Ltd., Hsinchu (TW)

(72) Inventor: Yan-Ru Su, Chiayi County (TW)

(73) Assignee: MACRONIX International Co., Ltd., Hsinchu (TW)

(21) Appl. No.: 17/939,762

(22) Filed: Sep. 7, 2022

(51) Int. Cl. H01L 27/11582; H01L 27/11565; H01L 27/11568

(52) U.S. Cl. CPC H01L 27/11582; H01L 27/11565; H01L 27/11568

(57) ABSTRACT

A memory device includes a stack structure, a channel pillar, a first conductive pillar, a second conductive pillar, a charge storage structure, a first conductive layer, a second conductive layer, and an insulating liner layer. The stack structure is located on a dielectric substrate and includes gate layers and insulating layers alternately stacked with each other. The channel pillar extends through the stack structure. The first conductive pillar and the second conductive pillar are located in and electrically connecting with the channel pillars. The charge storage structure is located between the gate layers and the channel pillar. The first conductive and the second conductive layers are located between the stack structure and the dielectric substrate. The second conductive layer is closer the channel layer than the first conductive layer. The insulating liner layer separates the second conductive layer from the channel layer and the first conductive layer.

### BACKGROUND

### Technical Field

The embodiment of the disclosure relates to a semiconductor device and a method of fabricating the same, and particularly, to memory device and a method of fabricating the same.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which can be applied to a multi-dimensional memory array with high integration and high area utilization, and has an advantage of a fast operation speed. Therefore, the development of a 3D memory device has gradually become the current trend.

### SUMMARY

The disclosure provides a memory device that can avoid abnormal electrical connection between a channel pillar or source pillar/a drain pillar and a conductive layer below a gate stack structure.

The disclosure provides a method of fabricating a memory device, which may be integrated with the existing process to avoid abnormal electrical connection between a channel pillar or a source pillar/a drain pillar and a conductive layer below a gate stack structure.

A memory device according to an embodiment of the disclosure includes a stack structure, a channel pillar, a first conductive pillar and a second conductive pillar, a charge storage structure, a first conductive layer, a second conductive layer and an insulating liner layer. The stack structure is located on a dielectric substrate, and the stack structure includes a plurality of gate layers and a plurality of insulating layers alternately stacked with each other. The channel pillar extends through the stack structure. The first conductive pillar and the second conductive pillar are located in the channel pillar and are electrically connected to the channel pillar. The charge storage structure is located between the gate layers and the channel pillar. The first conductive layer and the second conductive layer are located between the stack structure and the dielectric substrate. The second conductive layer is closer the channel pillar than the first conductive layer. The insulating liner layer separates the second conductive from the channel pillar and the first conductive layer.

A method of fabricating a memory device according to an embodiment of the disclosure includes the following steps. A first conductive layer is formed on a dielectric substrate. A stack structure is formed on the first conductive layer. The stack structure includes a plurality of intermediate layers and a plurality of insulating layers stacked alternately with each other. A channel pillar extending through the stack structure is formed. A first 1 pillar and a second pillar are formed in the channel pillar, and the first pillar and the second pillar are respectively electrically connected to the channel pillar. The intermediate layers adjacent to the channel pillar are replaced with a plurality of gate layers. A plurality of charge storage structures are formed between the gate layers and the channel pillar. The first conductive layer adjacent to the channel pillar are replaced with a second conductive layer. An insulating liner layer is formed between the channel pillar and the second conductive layer and between the first conductive layer and the second conductive layer.

Based on the above, in the memory device of the embodiments of the disclosure, the insulating liner layer is disposed between the second conductive layer below the gate stack structure to avoid abnormal electrical connection between the channel pillar or source pillar/the drain pillar and the second conductive layer below the gate stack structure.

### BRIEF DESCRIPTION OF THE DRAWINGS

FIG. 1A shows a circuit diagram of a 3D AND flash memory array according to some embodiments.

FIG. 1B shows a partial perspective view of a part of the memory array in FIG. 1A.

FIG. 1C and FIG. 1D show cross-sectional views taken along line I-I′ of FIG. 1B.

FIG. 1E shows a top view of line II-II′ of FIG. 1B, FIG. 1C, and FIG. 1D.

FIG. 2A to FIG. 2M are schematic cross-sectional views of a process of fabricating a memory device according to an embodiment of the disclosure.

FIG. 3, FIG. 4, and FIG. 5 are schematic cross-sectional views of memory devices according to other some embodiments of the disclosure.

FIG. 6A to FIG. 6C are schematic cross-sectional views of a process of fabricating another memory device according to an embodiment of the disclosure.

FIG. 7 is a schematic cross-sectional view of a memory device according to further embodiments of the disclosure.

### DESCRIPTION OF THE EMBODIMENTS

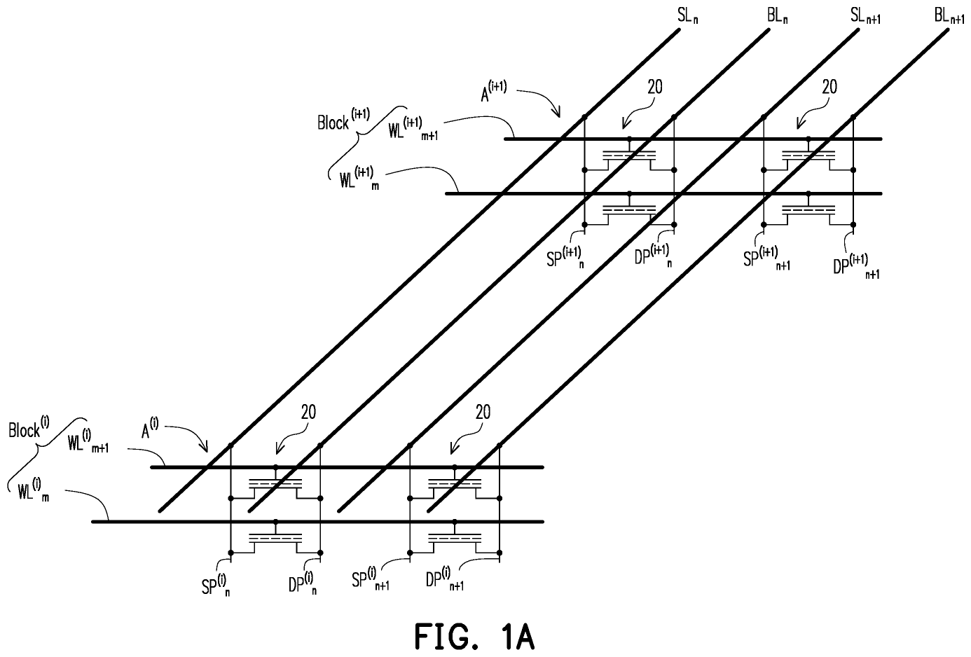

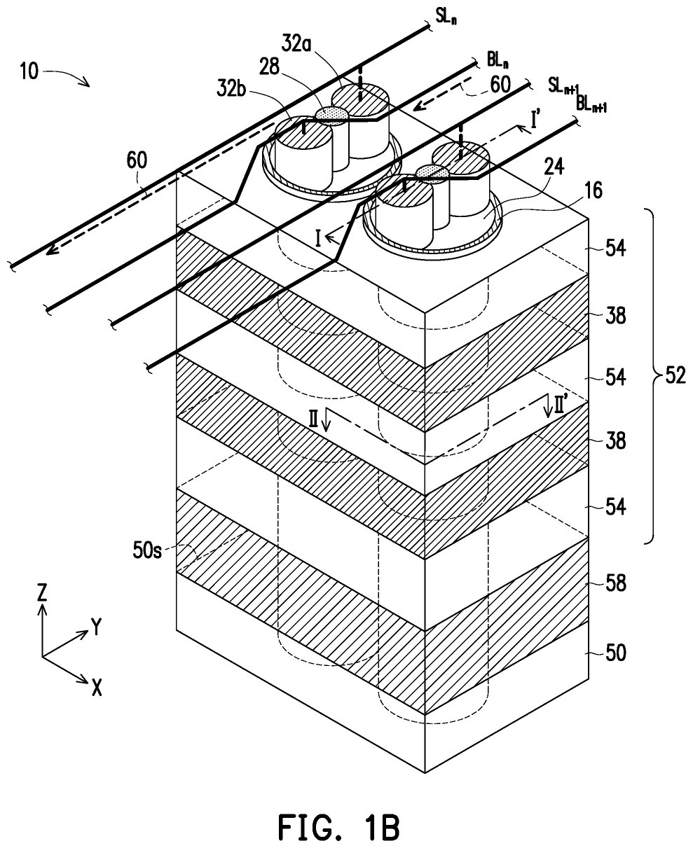

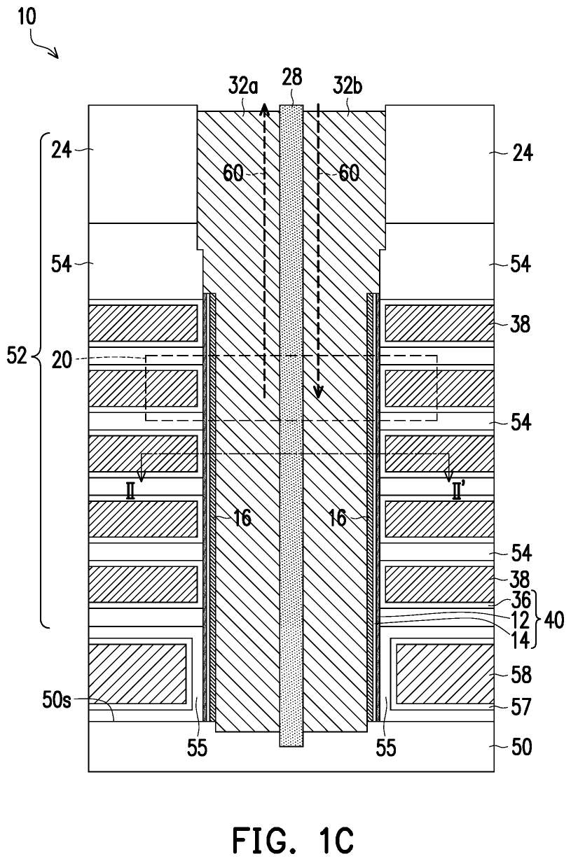

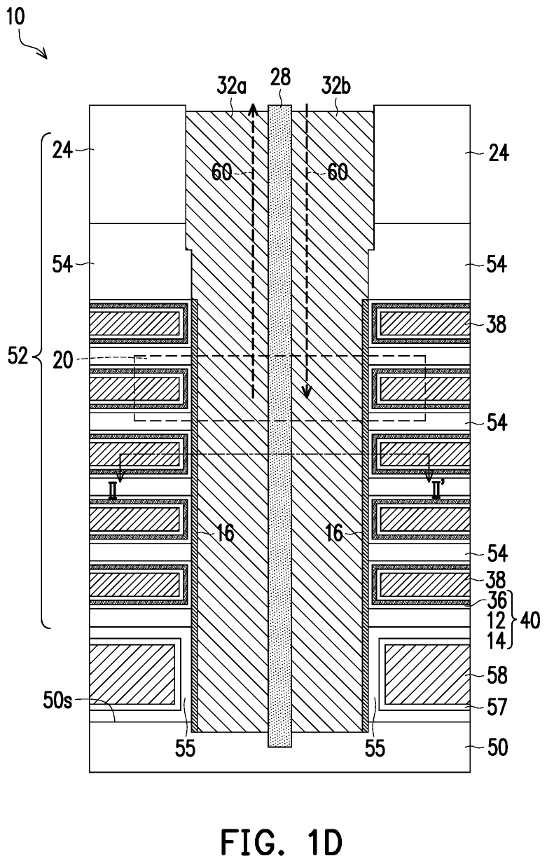

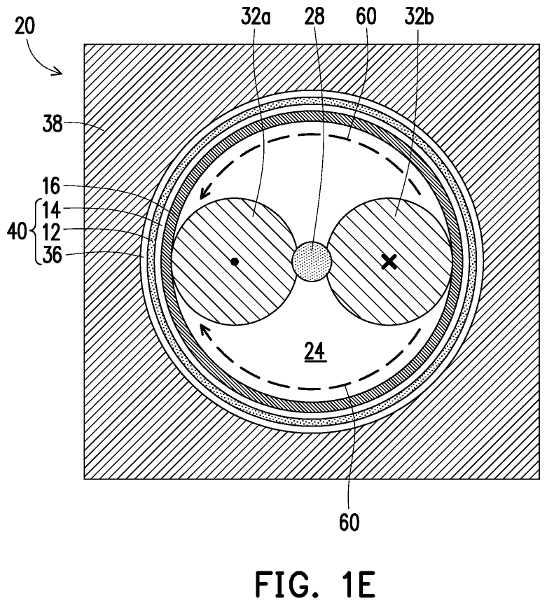

FIG. 1A shows a circuit diagram of a 3D AND flash memory array according to some embodiments. FIG. 1B shows a partial perspective view of a part of the memory array in FIG. 1A. FIG. 1C and FIG. 1D show a cross-sectional view taken along line I-I′ of FIG. 1B. FIG. 1E shows a top view of line II-II′ of FIG. 1B, FIG. 1C and FIG. 1D.

FIG. 1A shows a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed over an interconnect structure of a semiconductor die, for example, being disposed on one or more active devices (e.g., transistors) formed on a semiconductor substrate. Therefore, a dielectric substrate 50 is, for example, a dielectric layer (e.g., a silicon oxide layer) over a metal interconnect structure formed on a silicon substrate. The memory array 10 may include a gate stack structure 52, a plurality of channel pillars 16, a plurality of first conductive pillars (also referred to as source pillars) 32a, a plurality of second conductive pillars (also referred to as drain pillars) 32b, and a plurality of charge storage structures 40.

Referring to FIG. 1B, the gate stack structure 52 is formed on the dielectric substrate 50 in an array region, a staircase region (not shown) and extends to a portion of a peripheral region (not shown). The gate stack structure 52 includes a plurality of gate layers (also referred to as word lines) 38 and a plurality of insulating layer 54 vertically stacked on a surface 50s of the dielectric substrate 50. In the Z direction, the gate layers 38 are electrically isolated from each other by the insulating layer 54 disposed therebetween. The gate layer 38 extends in a direction parallel to the surface of the dielectric substrate 50. The gate layers 38 in the staircase region may have a staircase structure (not shown). Therefore, a lower gate layer 38 is longer than an upper gate layer 38, and the end of the lower gate layer 38 extends laterally beyond the end of the upper gate layer 38. A contact (not shown) for connecting the gate layer 38 may land on the end of the gate layer 38 to connect the gate layers 38 respectively to conductive lines.

Referring to FIG. 1B to FIG. 1D, the memory array 10 further includes a plurality of channel pillars 16. The channel pillar 16 continuously extends through the gate stack structure 52. In some embodiments, the channel pillar 16 may have a circular profile in a top view. The material of the channel pillar 16 may be semiconductor such as undoped polysilicon.

Referring to FIG. 1B to FIG. 1D, the memory array 10 further includes an insulating pillar 28, a plurality of first conductive pillars 32a, and a plurality of second conductive pillars 32b. In this example, the first conductive pillars 32a serve as source pillars. The second conductive pillars 32b serve as drain pillars. The first conductive pillar 32a, the second conductive pillar 32b, and the insulating pillar 28 each extend in a direction (i.e., the Z direction) perpendicular to the surface (e.g., the XY plane) of the gate layer 38. The first conductive pillar 32a and the second conductive pillar 32b are separated from each other by the insulating pillar 28. The first conductive pillar 32a and the second conductive pillar 32b are electrically connected to the channel pillar 16. The first conductive pillar 32a and the second conductive pillar 32b include doped polysilicon or metal materials. The insulating pillar 28 is, for example, silicon nitride or silicon oxide.

Referring to FIG. 1C and FIG. 1D, the charge storage structure 40 is disposed between the channel pillar 16 and the gate layers 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (the tunneling layer 14 and the charge storage layer 12) of the charge storage structure 40 continuously extends in a direction (i.e., the Z direction) perpendicular to the gate layer 38, and the other portion (the blocking layer 36) of the charge storage structure 40 surrounds the gate layer 38. In other embodiments, as shown in FIG. 1D, the charge storage structure 40 (the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

Referring to FIG. 1C to FIG. 1D, in some embodiments of the disclosure, the channel pillar 16, the source pillar 32a and the drain pillar 32b further extend to a conductive layer 58 located between the gate stack structure 52 and the conductive layer 58. The conductive layer 58 may be referred to as a dummy gate, and may be used to close the leakage path.

A material of the conductive layer 58 may include semiconductor or metal. The material of the conductive layer 58 may be the same as or different from the material of the gate layer 38. The material of the conductive layer 58 may also be the same or different from the material of the laterally adjacent conductive layer (not shown). The material of the laterally adjacent conductive layer (not shown) is, for example, a semiconductor or a metal. In some embodiments, the material of the conductive layer 58 and the laterally adjacent conductive layer (not shown) are a semiconductor, such as polysilicon, and the gate layer 38 is a metal, such as tungsten. In other embodiments, the material of the laterally adjacent conductive layer (not shown) is semiconductor, such as polysilicon; the material of the conductive layer 58 and the gate layer 38 is metal, such as tungsten.

The present invention also provides an insulating liner layer 55 to electrically isolate the conductive layer 58 from the channel pillar 16, or form the conductive pillars 32a and 32b. In some embodiments, the insulating liner layer 55 surrounds the conductive layer 58. The material of the insulating liner layer 55 may be completely or partially the same as the material of the charge storage structure 40. The insulating liner layer 55 may be a single layer or multiple layers. Materials for the insulating liner layer 55 include silicon oxide, silicon nitride, and high dielectric constant materials with a dielectric constant greater than or equal to 7, such as aluminum oxide (Al₁O₃), hafnium oxide (HfO₂), lanthanum oxide (La₂O₅), transition metal oxides, lanthanide oxides, or combinations thereof.

In some embodiments, a barrier layer 57 may be optionally disposed between the insulating liner layer 55 and the conductive layer 58. The material of the barrier layer 57 is, for example, titanium (Ti), titanium nitride (TiN), tantalum (Ta), tantalum nitride (TaN) or a combination thereof.

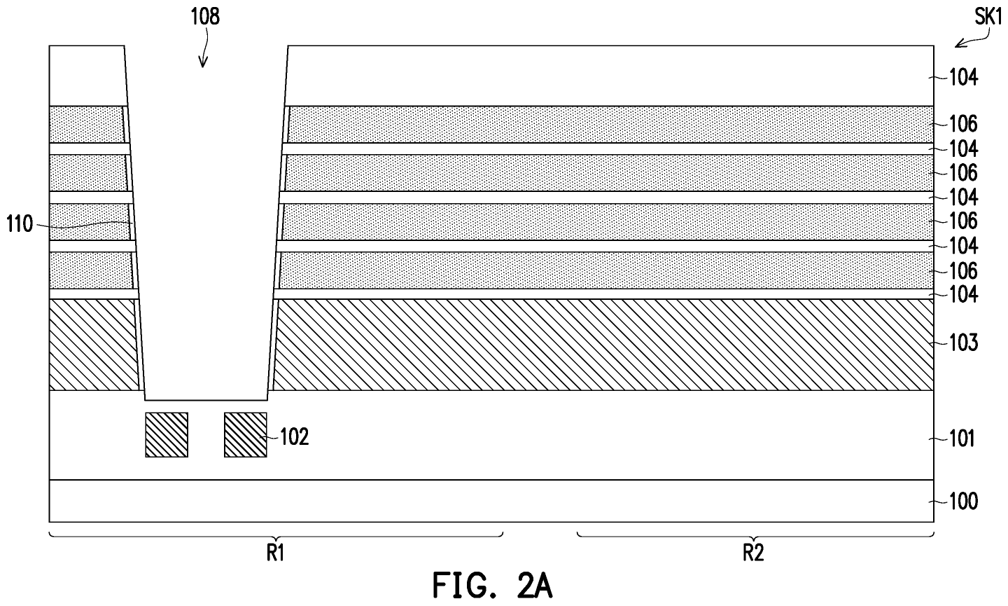

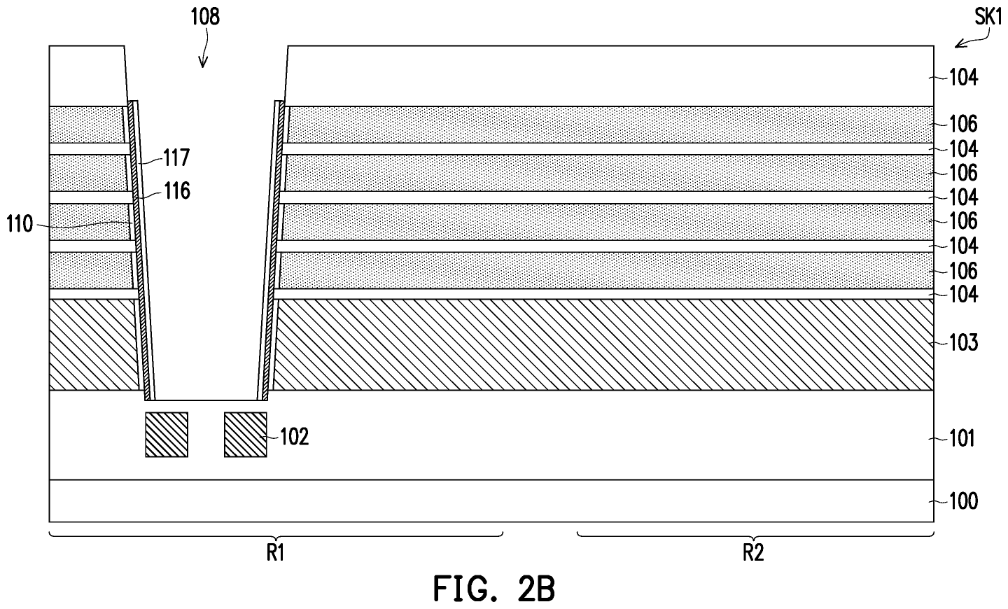

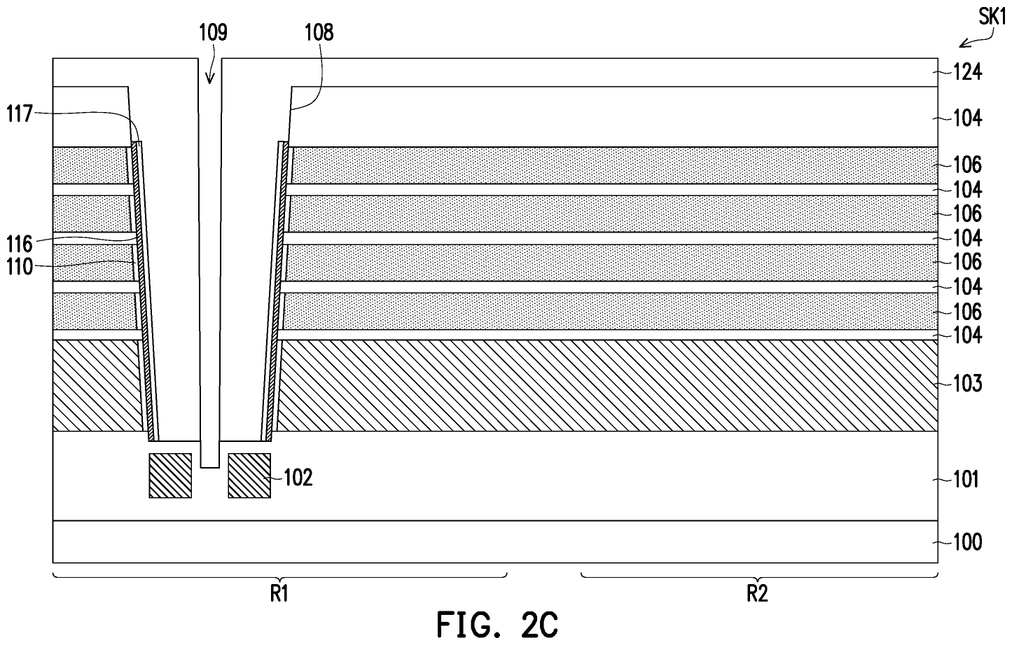

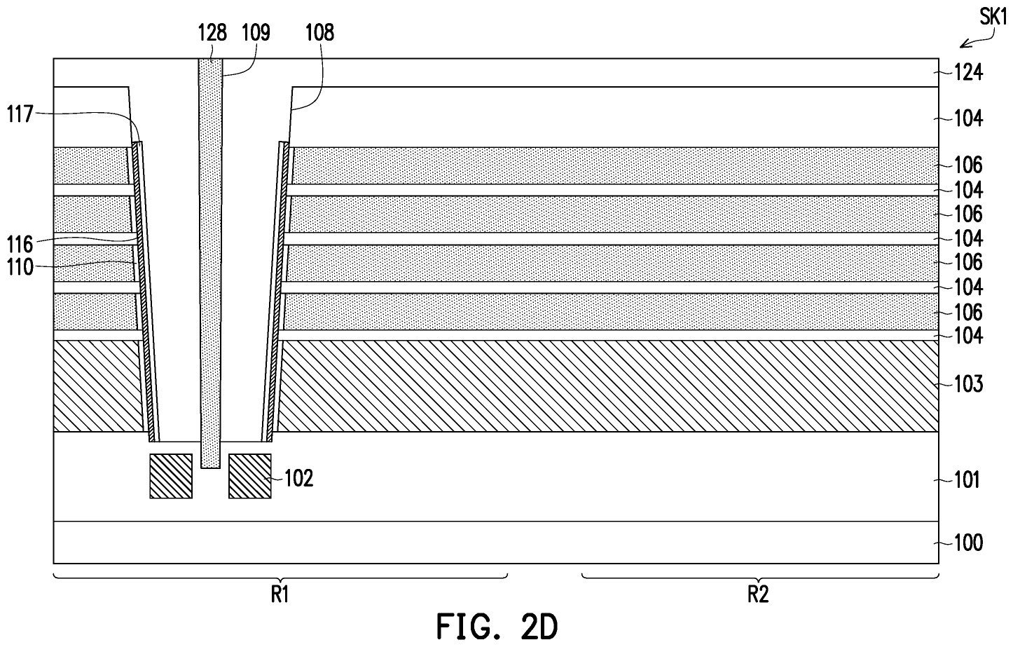

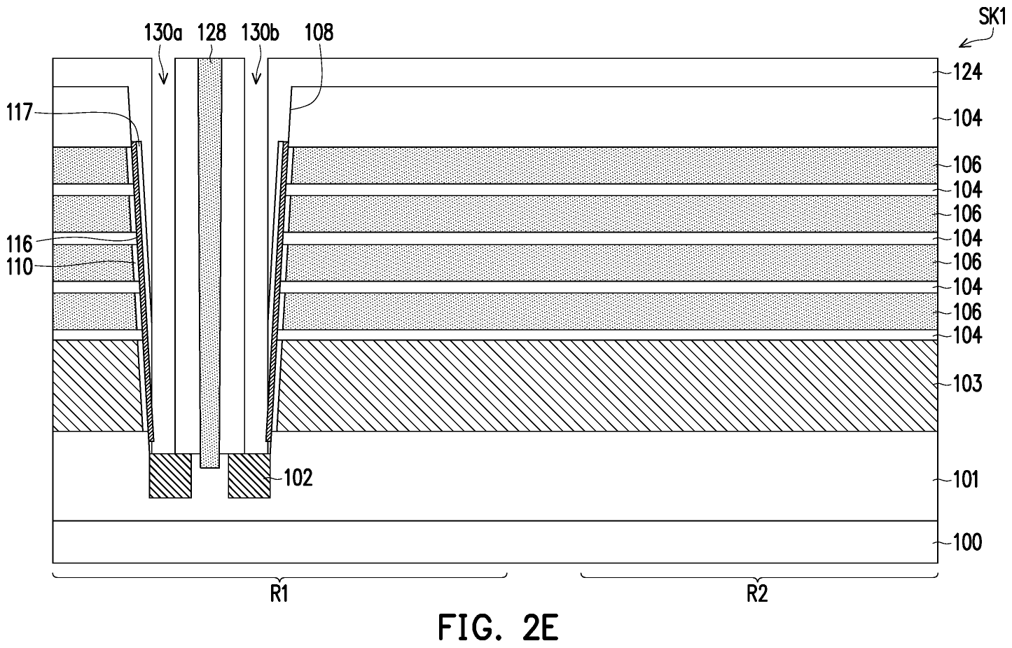

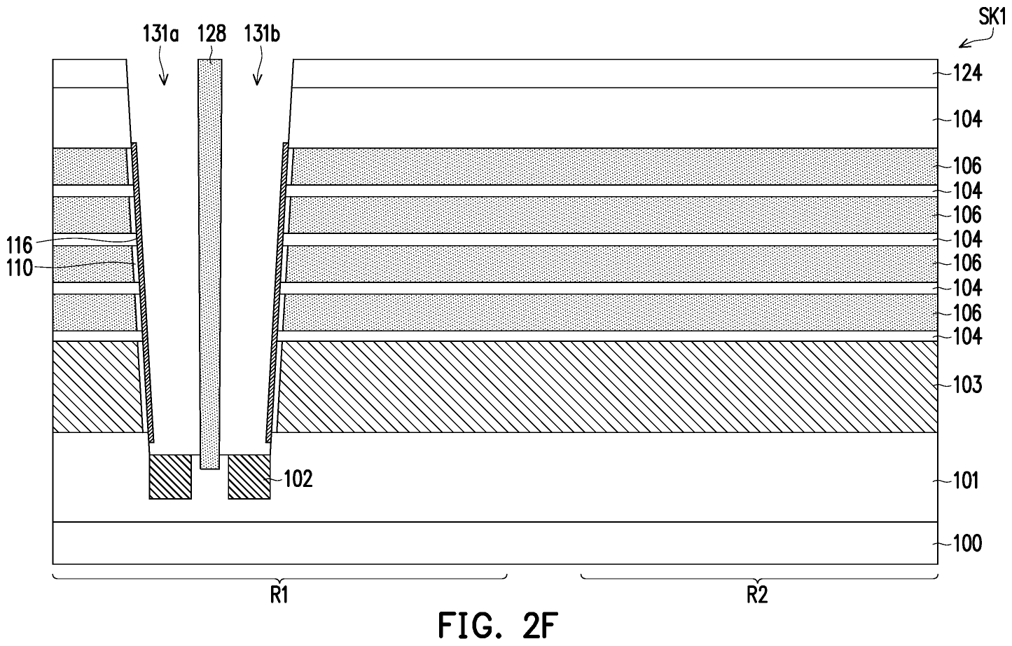

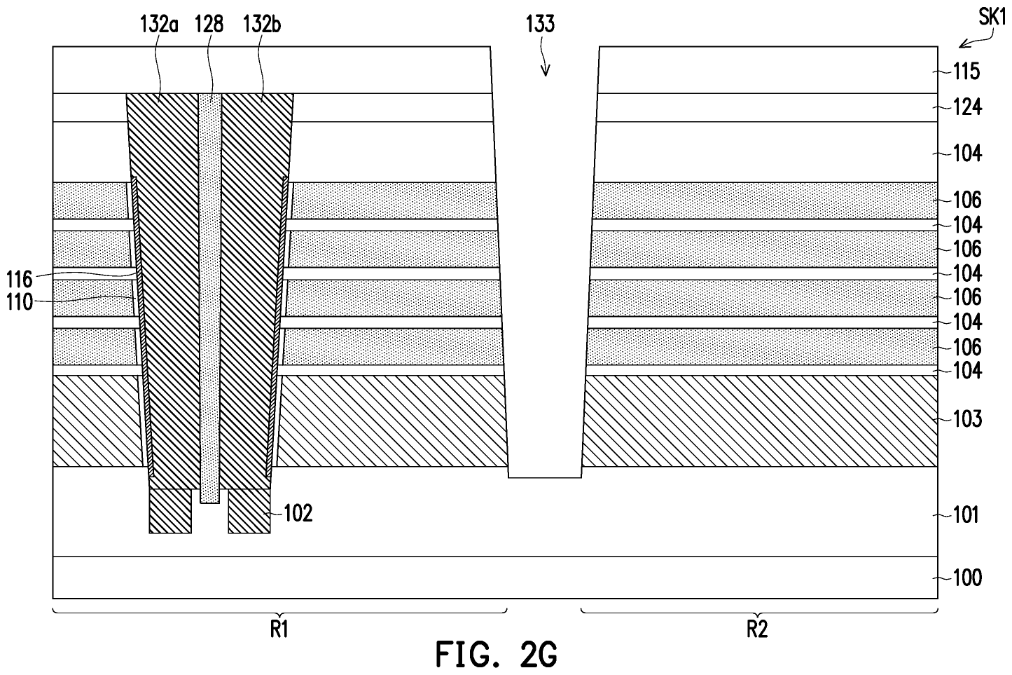

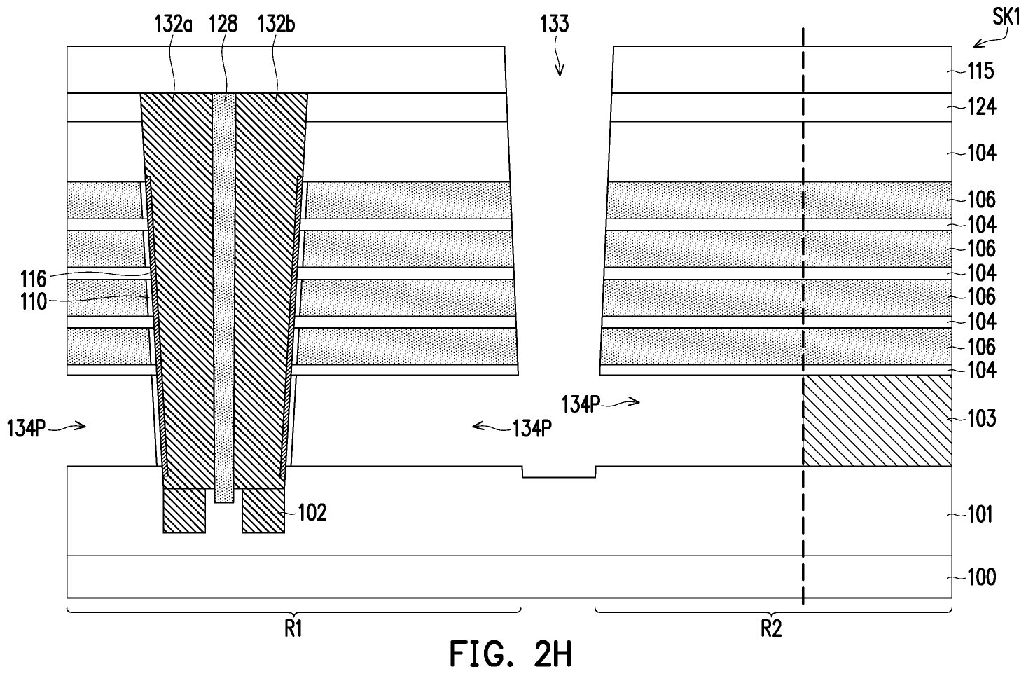

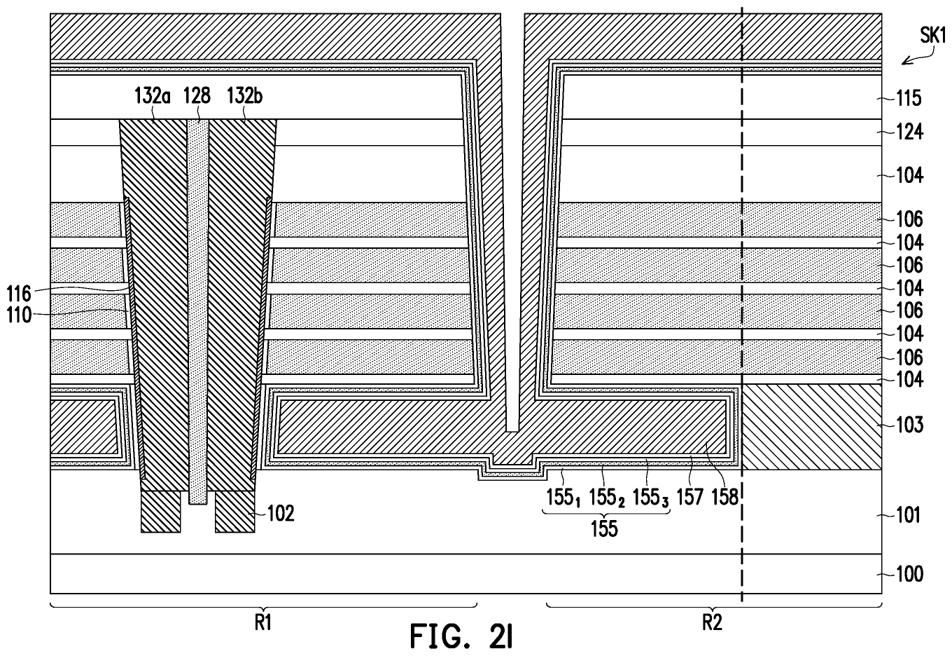

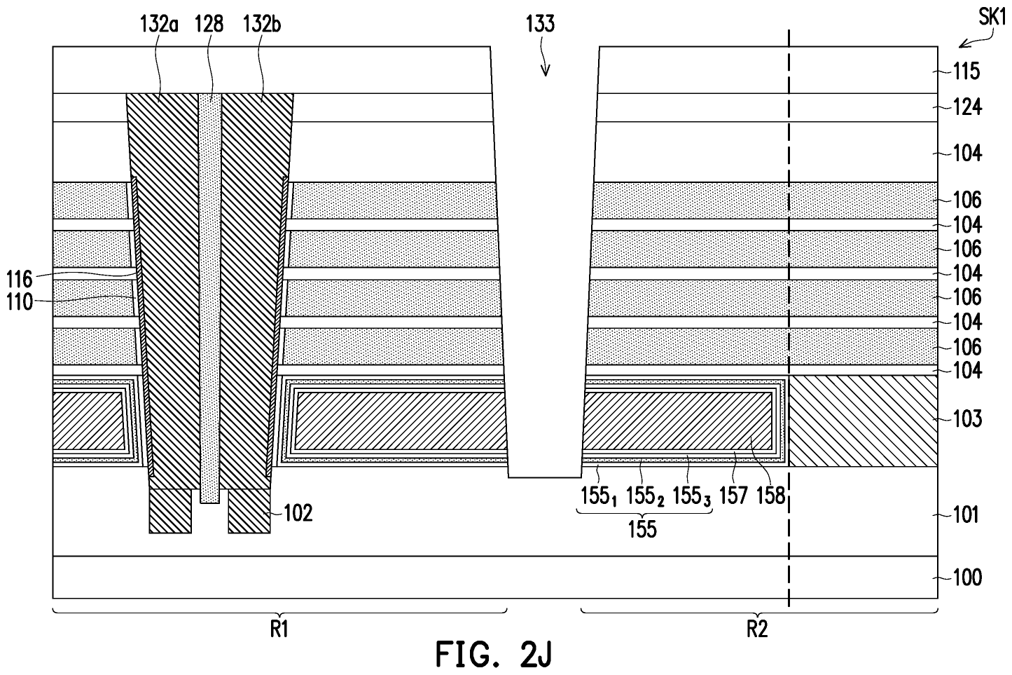

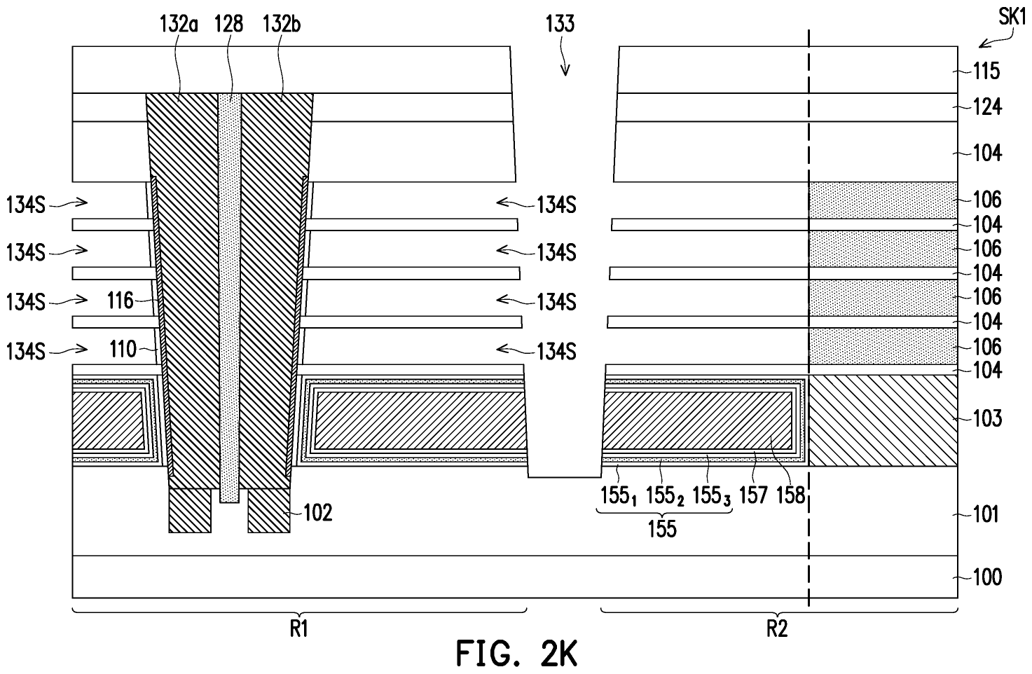

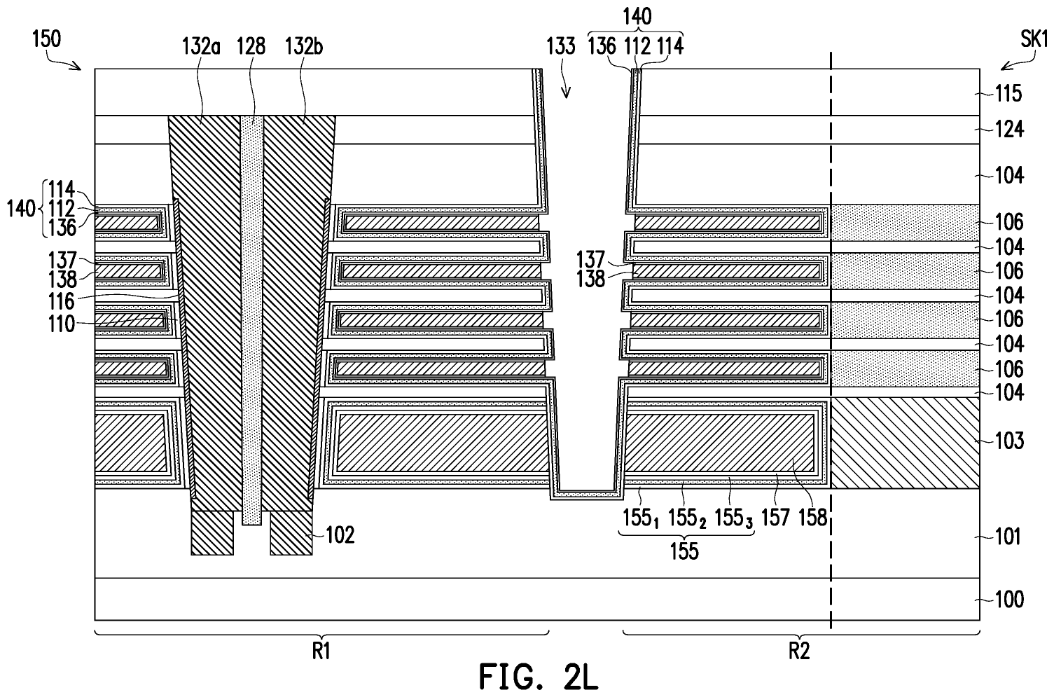

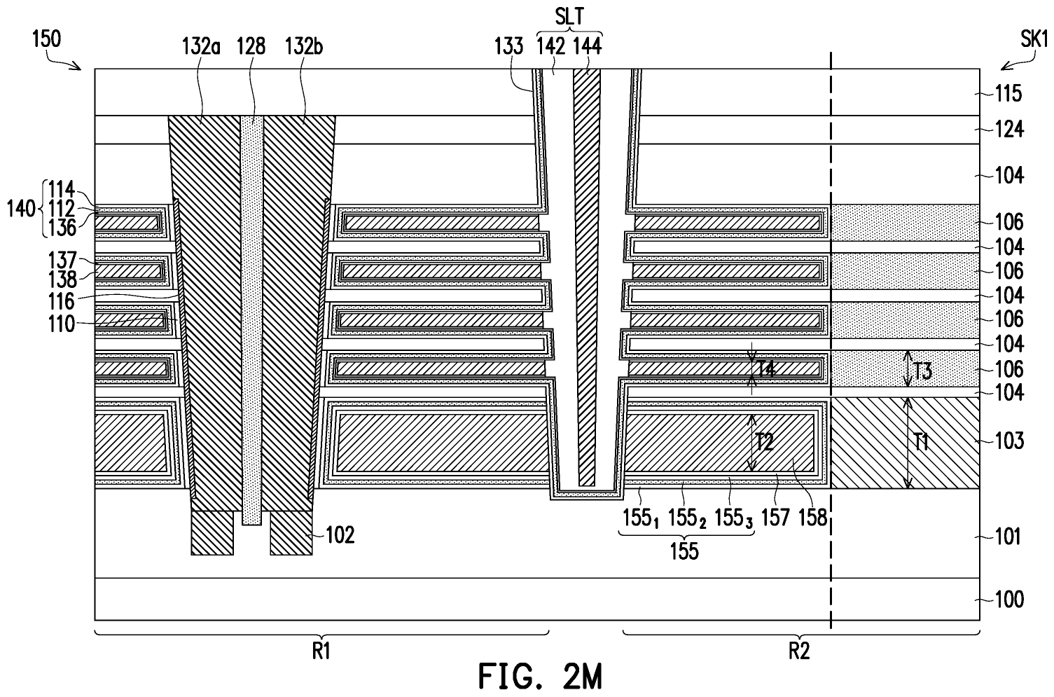

FIG. 2A to FIG. 2M are schematic cross-sectional views of a process of fabricating a memory device according to an embodiment of the disclosure.

Referring to FIG. 2A, a dielectric substrate 100 is provided. The dielectric substrate 100 is, for example, a dielectric layer (e.g., a silicon oxide layer) over a metal interconnect structure formed on a silicon substrate. The dielectric substrate 100 includes an array region R1, a peripheral region R2, and a staircase region (not shown). A stack structure SK1 is formed on the dielectric substrate 100 in the array region R1, the peripheral region R2, and the staircase region. The stack structure SK1 may also be referred to as an insulating stack structure SK1. In this embodiment, the stack structure SK1 is composed of insulating layers 104 and intermediate layers 106 that are sequentially alternately stacked on the dielectric substrate 100. In other embodiments, the stack structure SK1 may be composed of intermediate layers 106 and insulating layers 104 that are sequentially alternately stacked on the dielectric substrate 100. In addition, in this embodiment, the uppermost layer of the stack structure SK1 is the insulating layer 104. The insulating layer 104 is, for example, a silicon oxide layer. The intermediate layer 106 is, for example, a silicon nitride layer. The intermediate layer 106 may serve as a sacrificial layer which may be partially removed in the subsequent process. In this embodiment, the stack structure SK1 has five insulating layers 104 and four intermediate layers 106, but the disclosure is not limited thereto. In other embodiments, more insulating layers 104 and more intermediate layers 106 may be formed according to the actual requirements.

In some embodiments, before the stack structure SK1 is formed, an insulating layer 101, a stop layer 102, and a conductive layer 103 are first formed on the dielectric substrate 100. The insulating layer 101 is, for example, silicon oxide. The stop layer 102 is formed in the insulating layer 101. The stop layer 102 is, for example, a conductive pattern such as a polysilicon pattern. The conductive layer 103 is, for example, a grounded polysilicon layer. The conductive layer 103 may also be referred to as a dummy gate, which may be used to close a leakage path. The stack structure SK1 is patterned to form a staircase structure in the staircase region.

Next, referring to FIG. 2A, a plurality of openings 108 are formed in the stack structure SK1 in the array region R1. In this embodiment, the opening 108 extends through the conductive layer 103, and the bottom surface of the opening 108 does not expose the stop layer 102 and the insulating layer 101, but the disclosure is not limited thereto. In this embodiment, in a top view, the opening 108 has a circular profile (not shown), but the disclosure is not limited thereto. In other embodiments, the opening 108 may have a profile of other shapes such as a polygonal shape (not shown).

Referring to FIG. 2B, a protection layer 110, a channel pillar 116, and a spacer 117 are formed in the opening 108. The protection layer 110 is formed on the sidewall of the intermediate layer 106. The protection layer 110 is, for example, a silicon oxide layer. The material of the channel pillar 116 may be semiconductor such as undoped polysilicon. The spacer 117 is, for example, a low-temperature silicon oxide layer. The method of forming the protection layer 110 is, for example, thermal oxidation. The method of forming the channel pillar 116 and the spacer 117 includes, for example, forming a channel material and a spacer material on the stack structure SK1 and in the opening 108. Then, an etch-back process is performed to partially remove the channel material and the spacer material to form the channel pillar 116 and the spacer 117. The channel pillar 116 and the spacer 117 cover the sidewall of the opening 108 and expose the bottom of the opening 108. The channel pillar 116 and the spacer 117 may extend through the stack structure SK1 and extend into the insulating layer 101 but are not limited thereto. In a top view, the channel pillar 116 has, for example, a ring shape, and the channel pillar 116 may be continuous in its extending direction (e.g., in a direction perpendicular to the dielectric substrate 100). In other words, the channel pillar 116 is integral in its extending direction and is not divided into multiple disconnected parts. In some embodiments, the channel pillar 116 may have a circular profile in a top view, but the disclosure is not limited thereto. In other embodiments, the channel pillar 116 may also have a profile of other shapes (e.g., a polygonal shape) in a top view. The protection layer 110 and the spacer 117 are respectively located on two sidewalls of the channel pillar 116.

Referring to FIG. 2C, an insulating filling material is formed on the stack structure SK1 and filled in the opening 108. The insulating filling material is, for example, a low-temperature silicon oxide. The insulating filling material filled in the opening 108 forms an insulating filling layer 124, and a circular seam is left at the center of the insulating filling layer 124. Then, an anisotropic etching process is performed to expand the circular seam to form a hole 109. In this embodiment, the hole 109 extends through the conductive layer 103, and the bottom surface of the hole 109 is located between the top surface and the bottom surface of the stop layer 102, but the disclosure is not limited thereto.

Referring to FIG. 2D, an insulating material is formed on the insulating filling layer 124 and in the hole 109. Then, an anisotropic etching process is performed to remove part of the insulating material to form an insulating pillar 128 in the hole 109. The material of the insulating pillar 128 is different from the material of the insulating filling layer 124. The material of the insulating pillar 128 is, for example, silicon nitride.

Referring to FIG. 2E, a patterning process (e.g., photolithography and etching processes) is performed to form holes 130a and 130b in the insulating filling layer 124. In the etching process, the stop layer 102 may serve as an etch stop layer. Therefore, the formed holes 130a and 130b extend from the stack structure SK1 until the stop layer 102 is exposed. The profiles of the hole patterns defined in the patterning process may be tangent to the profile of the insulating pillar 128 (not shown). The profiles of the hole patterns defined in the patterning process may also exceed the profile of the insulating pillar 128 (not shown). Since the etching rate of the insulating pillar 128 is lower than the etching rate of the insulating filling layer 124, the insulating pillar 128 is hardly damaged by etching and remains. In addition, in some embodiments, the profiles of the hole patterns defined in the patterning process exceed the profile of the opening 108, so that the upper sidewalls of the holes 130a and 130b expose part of the top insulating layer 104 of the stack structure SK1. The middle sidewalls and the lower sidewalls of the holes 130a and 130b expose the insulating layer 101, the insulating pillar 128, and the spacer 117.

Referring to FIG. 2F, next, an etch-back process or a pull-back process is performed to remove the spacer 117 exposed on the sidewalls of the holes 130a and 130b so as to form hole 131a and 131b exposing the channel pillar 116 and the insulating pillar 128. In some embodiments, during the etching process, the lower portion of the channel pillar 116, or even the protective layer 110 between the lower portion of the channel pillar 116 and the conductive layer 103 may be damaged due to improper control of the etching conditions. The sidewalls of the conductor layer 103 are exposed. In this way, the subsequently formed conductive pillars 132a and 132b will be short-circuited with the conductive layer 103.

Referring to FIG. 2G, conductive pillars 132a and 132b are formed in the hole 131a and 131b. The conductive pillars 132a and 132b may be used as a source pillar and a drain pillar to be electrically connected to the channel pillar 116, respectively. The conductive pillars 132a and 132b are formed by, for example, forming a conductive material on the substrate 100 and filling in the holes 131a and 131b, and performing an etch-back process. The material of the conductive pillars 132a and 132b is, for example, doped polysilicon.

Referring to FIG. 2G, a cap insulating layer 115 is formed on the stack structure SK1. A material of the cap insulating layer 115 includes silicon oxide. Afterwards, patterning process (e.g., photolithography and etching processes) is performed on cap insulating layer 115 and the stack structure SK1 to form a plurality of slit trenches 133. In the etching process, the insulating layer 101 or the conductive layer 103 may serve as an etch stop layer, so that a bottom of the slit trench 133 exposes the insulating layer 101 or the conductive layer 103.

Referring to FIG. 2H to FIG. 2J, a replacement process is performed to the conductive layer 103. Referring to FIG. 2H, first, an etching process such as a wet etching process is performed to remove the conductive layer 103 adjacent to the slit trenches 133 in the array region R1, the staircase region, and the peripheral region R2. An etching solution (e.g., hot phosphoric acid) used in the etching process is injected into the slit trenches 133, and then the conductive layer 103 exposed by the slit trenches 133 is removed to form a horizontal opening 134P. The conductive layer 103 far from the slit trenches 133 is left. In some embodiments, the horizontal opening 134P reveals the insulating layers 101 and 104, the remaining conductive layer 103 and the protection layer 110. In other some embodiment, the protection layer 110 on the sidewalls of the conductive layer 103 and a lower portion of the conductive pillars 116 are etched, so that the horizontal opening 134P reveals the insulating layers 101 and 104, the remaining conductive layer 103, and the conductive pillars 132a and 132b.

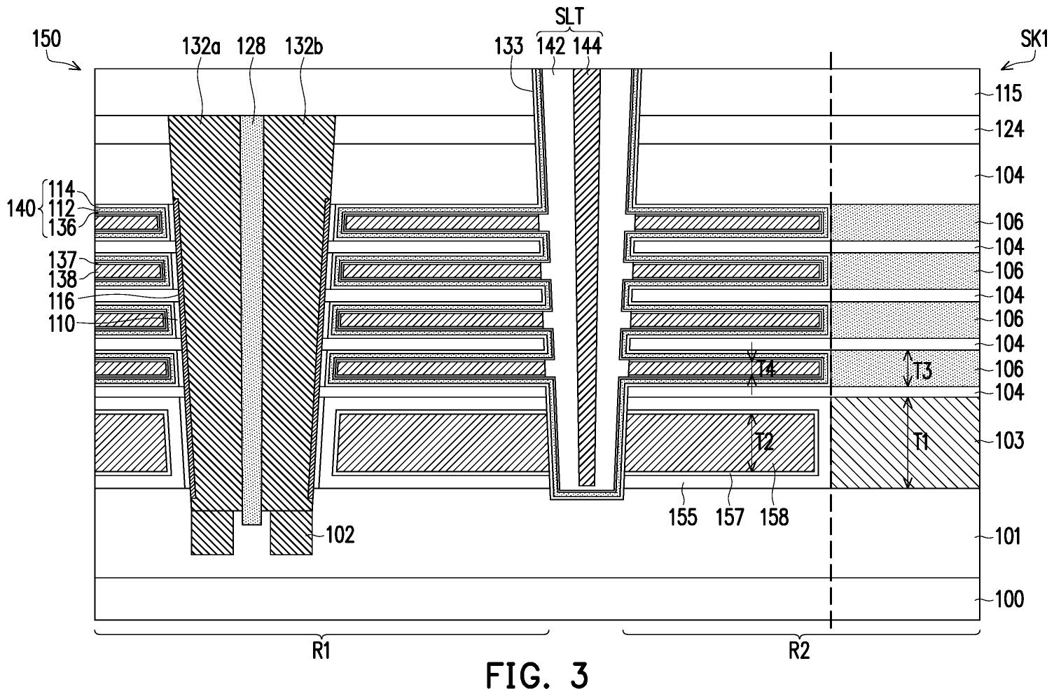

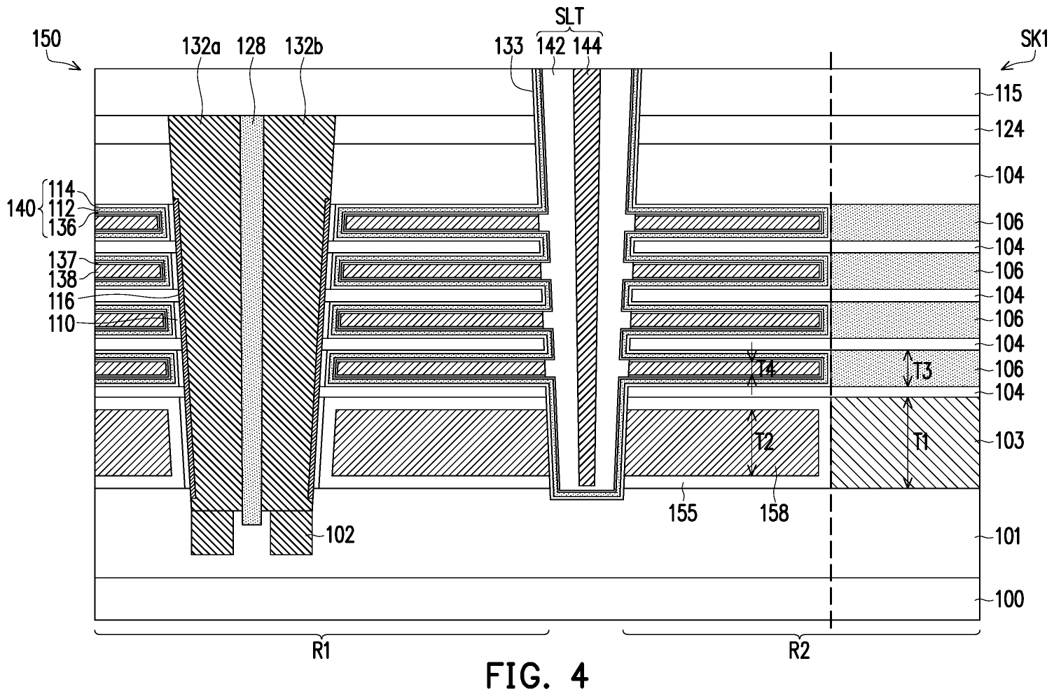

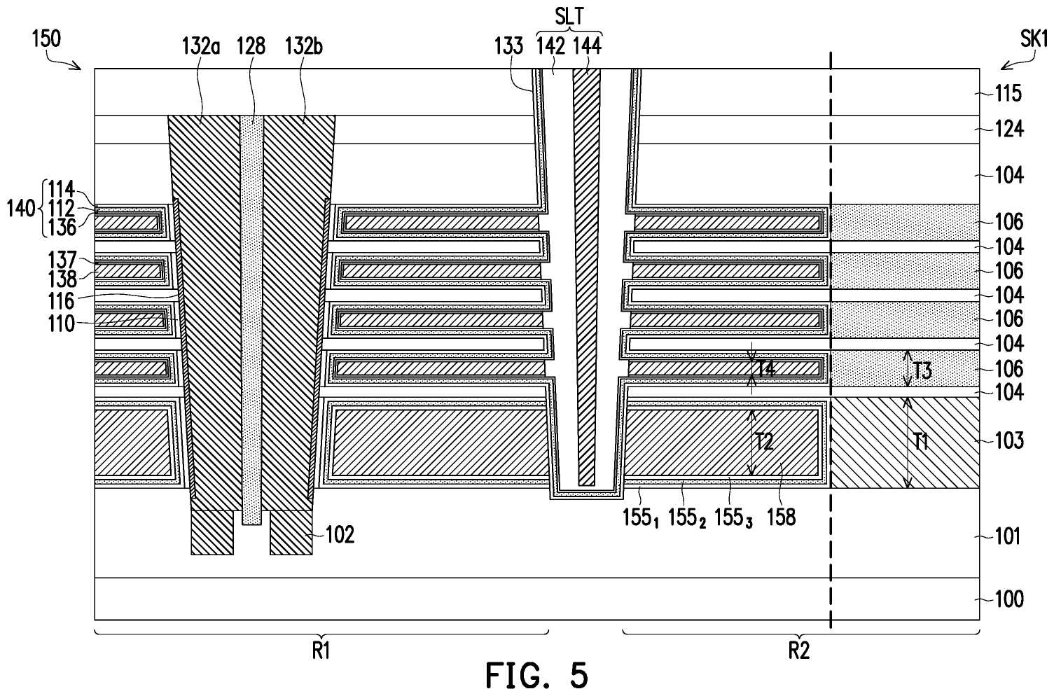

Referring to FIG. 2I, an insulating liner layer 155 and a conductive layer 158 are formed in the slit trench 133 and the horizontal opening 134P. The insulating liner layer 155 may include multiple layers, such as layers 155₁, 155₂, and 155₃. In some embodiments, the layer 155₁ is, for example, silicon oxide, the layer 155₂ is, for example, silicon nitride, and the layer 155₃ is, for example, silicon oxide. In other embodiments, the materials of the layers 155₁, 155₂, and 155₃ may be the same as the materials of the subsequently formed tunneling layer 114, charge storage layer 112, and blocking layer 136, respectively. In another embodiment, the insulating liner layer 155 may be a single layer, such as silicon oxide, as shown in FIGS. 3 and 4.

In some implementations, the material of conductive layer 158 is different from the material of conductive layer 103. The material of the conductive layer 158 may be the same as a material of gate layers 138 to be formed later. The material of the conductive layer 158 may be metal, such as tungsten. In some embodiments, barrier layers 157 are also formed before the gate layers 138 are formed. The material of the barrier layers 157 is, for example, titanium (Ti), titanium nitride (TiN), tantalum (Ta), tantalum nitride (TaN) or a combination thereof.

Thereafter, referring to FIG. 2I, an etch-back process or a planarization process is performed, and the insulating liner layer 155, the barrier layer 157 and the conductive layer 158 on the cap insulating layer 115 are removed first. Next, the etch-back process is performed continuously to remove the insulating liner layer 155, the barrier layers 157 and the conductive layer 158 in the plurality of slit trenches 133. The insulating liner layer 155, the barrier layers 157, and the conductive layer 158 in the horizontal opening 134P are left.

Thereafter, referring to FIG. 2K to FIG. 2L, a replacement process is performed to the intermediate layers 106. Referring to FIG. 2K, first, an etching process such as a wet etching process is performed to remove the intermediate layers 106 adjacent to the slit trenches 133 in the array region R1, the staircase region, and the peripheral region R2. An etching solution (e.g., hot phosphoric acid) used in the etching process is injected into the slit trenches 133, and then the contacted portion of the intermediate layers 106 is removed. When the intermediate layers 106 between the channel pillar 116 and the slit trench 133 are removed, since the material of the protection layer 110 is different from the material of the intermediate layer 106, the protection layer 110 may serve as an etch stop layer to protect the channel pillar 116. The etching process is continued, and through time mode control, most of the intermediate layers 106 are removed to form a plurality of horizontal openings 134S. The intermediate layers 106 far from the slit trenches 133 are left. The horizontal openings 134S reveal the protection layer 110 and the remaining intermediate layers 106. The protection layer 110 may be removed by an etching process or be left.

Referring to FIG. 2L, a plurality of tunneling layers 114, a plurality of charge storage layers 112, a plurality of blocking layers 136, and a plurality of gate layers 138 are formed in the horizontal openings 134S. The material of the tunneling layer 114 is, for example, silicon oxide. The material of the charge storage layer 112 is, for example, silicon nitride. The material of the blocking layer 136 is, for example, a high dielectric constant material having a dielectric constant greater than or equal to 7, such as aluminum oxide (Al₁O₃), hafnium oxide (HfO₂), lanthanum oxide (La₂O₅), transition metal oxide, lanthanide oxide, or combinations thereof. The material of the gate layer 138 is, for example, tungsten. In some embodiments, before the gate layers 138 are formed, a barrier layers 137 is formed. The material of the barrier layer 137 is, for example, titanium (Ti), titanium nitride (TiN), tantalum (Ta), tantalum nitride (TaN), or a combination thereof.

The method of forming the tunneling layer 114, the charge storage layer 112, the blocking layer 136, the barrier layer 137, and the gate layer 138 includes, for example, sequentially forming a tunneling material, a storage material, a blocking material, a barrier material, and a conductive material in the slit trench 133 and the horizontal opening 134S. Then, an etch-back process is performed so as to form the tunneling layer 114, the charge storage layer 112, the blocking layer 136, the barrier layer 137, and the gate layer 138 in the horizontal openings 134S. In some embodiments, the barrier material and the conductive material in the slit trenches 133 are removed, while the tunneling material, the charge storage material, and the blocking material are left, so that the tunneling layer 114, the charge storage layer 112, and the blocking layer 136 extends from the horizontal openings 134S to the slit trench 133. In other some embodiments, the tunneling material, the charge storage material, the blocking material, the barrier material and the conductive material in the slit trenches 133 are removed (not shown). The tunneling layer 114, the charge storage layer 112, and the blocking layer 136 are collectively referred to as a charge storage structure 140. At this time, a gate stack structure 150 is formed.

The gate stack structure 150 is around the channel pillars 116, while the stack structure SK1 is far from the channel pillars 116. The layers consisting the gate stack structure 150 are different from the layers consisting the gate stack structure 150. The gate stack structure 150 is disposed over the conductive layer 158 and includes a plurality of gate layers 138 and a plurality of insulating layers 104 stacked alternately with each other. The stack structure SK1 is disposed over the conductive layer 103 and includes a plurality of intermediate layers 106 and a plurality of insulating layers 104 stacked alternately with each other. The insulating liner layer 155 separates the conductive layer 158 that is below the gate stack structure 150 and adjacent the channel pillar 116 from the conductive layer 103 that is below the stack structure SK1.

Referring to FIG. 2M, a slit SLT is formed in the slit trench 133. The method of forming the slit SLT includes filling an insulating liner material and a conductive material on the gate stack structure 150 and in the slit trench 133. The insulating material is, for example, silicon oxide. The conductive material is, for example, polysilicon. Then, the excessive insulating liner material and conductive material on the gate stack structure 150 is removed through an etch-back process or a planarization process to form a liner layer 142 and a conductive layer 144. The liner layer 142 and the conductive layer 144 are collectively referred to as a slit SLT. In other embodiments, the slit SLT may also be fully filled with an insulating material without any conductive layer. In still other embodiments, the slit SLT may also be a liner layer 142, and the liner layer 142 covers an air gap without any conductive layer.

In some embodiments, the charge storage structure 140 on sidewalls of the slit trench 133 is left, and thus the charge storage structure 140 surrounds the slit SLT and sandwiched between the conductive layer 158 and the slit SLT as shown in FIG. 2M. In other some embodiments, the charge storage structure 140 on sidewalls of the slit trench 133 is removed, and thus the conductive layer 158 is in contact with the slit SLT, and the insulating layers 104 are in contact with the slit SLT (not shown).

Afterwards, a contact (not shown) is formed in the staircase region. The contact lands on the end of the gate layer 138 in the staircase region and is electrically connected thereto.

In the embodiment of the present invention, the insulating liner layer 155 and the barrier layer 157 surround the conductive layer 158. The insulating liner layer 155 is interposed between and electrically isolates the conductive layers 158 and 153. The insulating liner layer 155 is interposed between and electrically isolates the conductive layer 158 and the channel pillar 116. Since the insulating liner layer 155 of the embodiment of the present invention can at least cover the sidewall of the conductive layer 158, the electrical isolation effect between the conductive layer 158 and the channel pillar 116 can be improved.

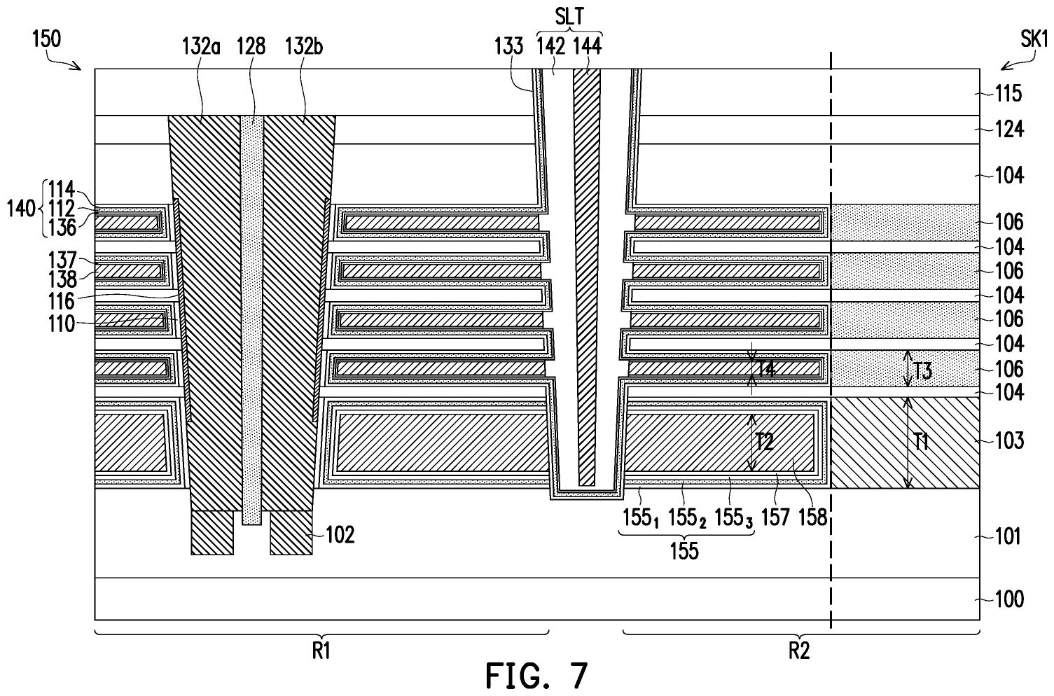

Referring to FIG. 2E, FIG. 2G and FIG. 7, in some cases, when forming the holes 130a, 130b, or 131a, 131b due to misalignment, over-etching or other process factors, resulting in lower parts of the conductive pillars 132a and 132b formed in the holes 131a and 131b are separated from the conductive layer 103 only by the protective layer 110, as shown in FIG. 7. The present invention can increase the distance between the conductive pillars 132a, 132b and the conductive layer 158 through the formation of the insulating liner layer 155 to improve the effect of electrical isolation.

In other embodiments, the insulating liner layer 155 may be a single layer, and the material thereof is, for example, silicon oxide, as shown in FIG. 3 and FIG. 4. A thickness of the insulating liner layer 155 may be greater than that of the tunneling layer 114, the charge storage layer 112, or the blocking layer 136.

In FIGS. 2A to 2M, the conductive layer 158 that is near the channel pillar 116 and the conductive layer 103 that is far from the channel pillar 116 are separated by the insulating liner layer 155. The material of the conductive layer 158 is different from that of the conductive layer 103, but is the same as that of the gate layer 138. The material of the conductive layer 158 and the gate layer 138 is, for example, tungsten, and the material of the conductive layer 103 is, for example, polysilicon.

FIG. 4 and FIG. 5, in another embodiment, the material of the conductive layer 158 is the same as the material of the conductive layer 103, and the material of the conductive layer 158 may be different from the material of the gate layer 138. The conductive layer 158 and the conductive layer 103 are made of polysilicon, for example, and there is no barrier layer 157 sandwiched between the conductive layer 158 and the insulating liner layer 155.

In the above embodiment, the conductive layer 158 and the gate layer 138 are formed through two etching processes used to form the horizontal openings 133S and 133P and two replacement processes. However, the present invention is not limited thereto. The horizontal openings 133S and 133P can be formed at the same time, and the conductive layer 158 and the gate layer 138 can also be formed at the same time.

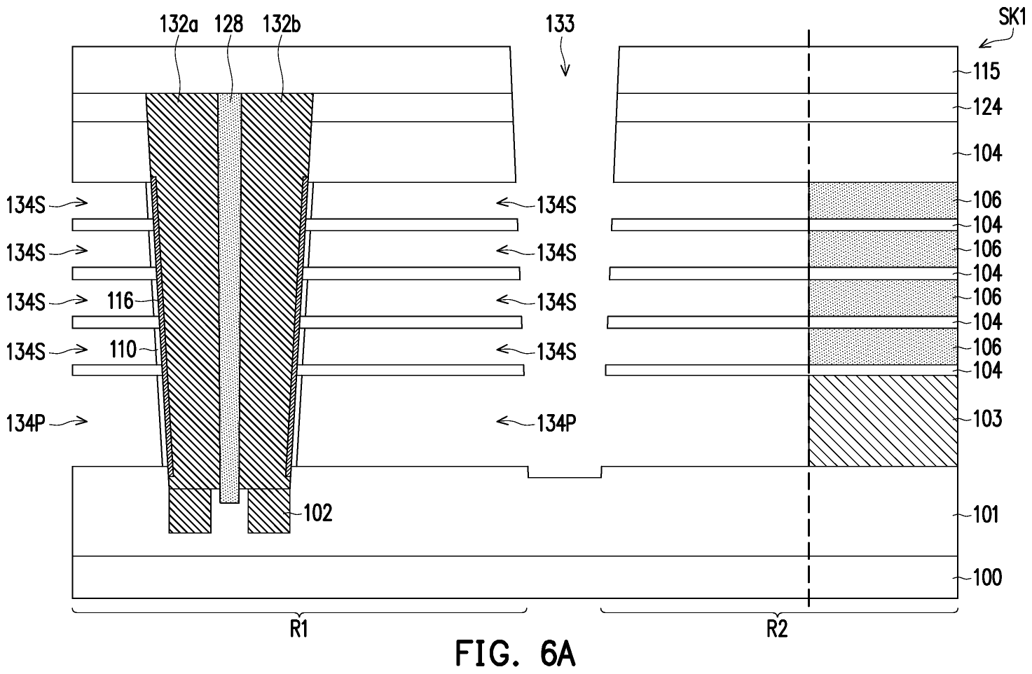

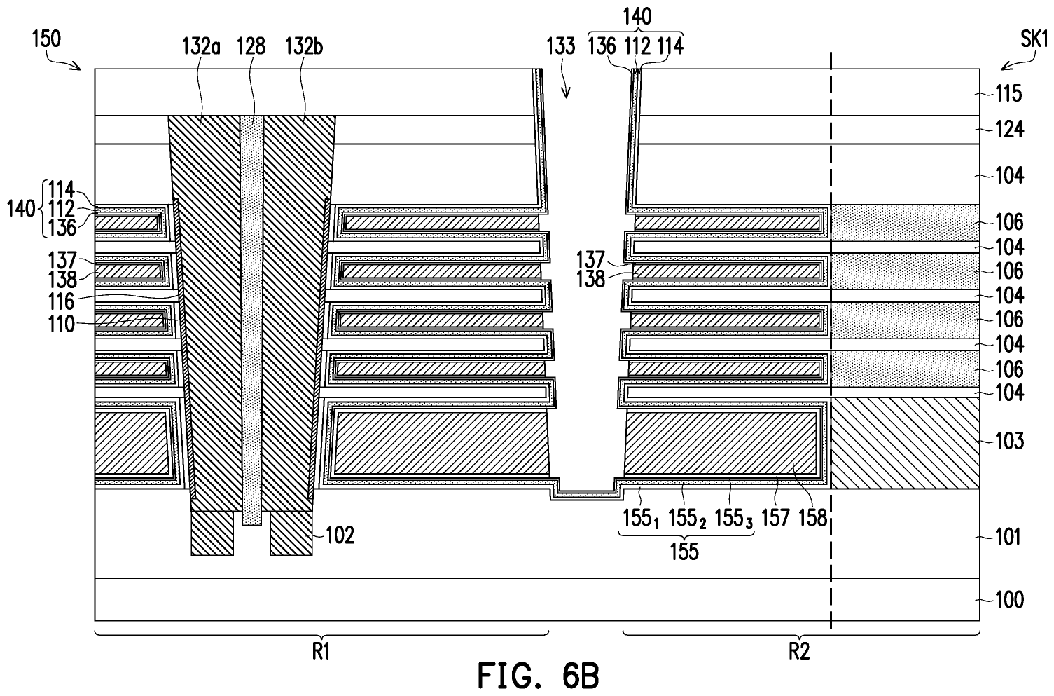

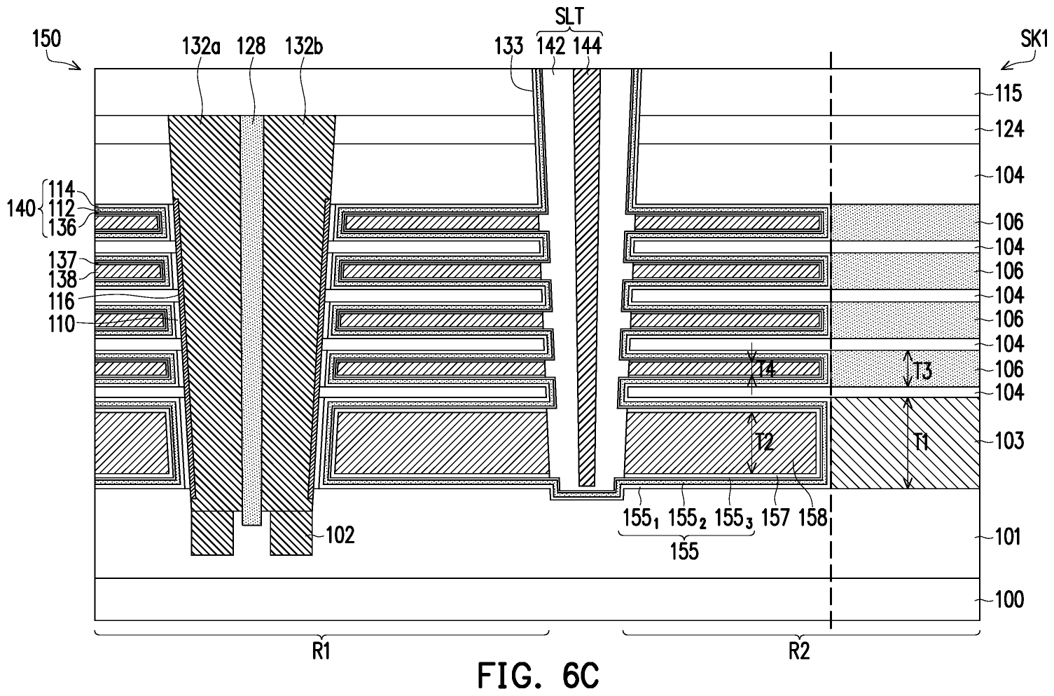

FIG. 6A to FIG. 6C are schematic cross-sectional views illustrating a manufacturing process of another memory device according to an embodiment of the present invention.

Referring to FIG. 6A, according to the method of the above-mentioned embodiment, the cap insulating layer 115 and the stacked structure SK1 are subjected to a patterning process, such as a lithography and an etching process, to form a slit trench 133. Next, an etching process is performed to remove the conductive layer 103 and the intermediate layer 106 in the array region R1, the staircase region and a portion of the peripheral region R2 to form the horizontal openings 133P and 133S.

Referring to FIG. 6B, a tunneling material, a charge storage material, a blocking material, a barrier material and a conductive material are sequentially formed in the slit trench 133 and the horizontal openings 134P and 134S, and then an etch-back process is performed to form layers 155₁, 155₂, 155₃ of an insulating liner layer 155, a barrier layer 157 and a conductive layer 158 in the horizontal opening 134P, and form a tunneling layer 114, a charge storage layer 112, a blocking layer 136, barrier layers 137 and gate layers 138 in the horizontal openings 134S. In this embodiment, the layers 155₁, 155₂, 155₃ are respectively connected to the tunneling layer 114, the charge storage layer 112, and the blocking layer 136 continuously. The barrier layers 157 and 137 are disconnected. The conductive layer 158 is disconnected to the gate layers 138.

Referring to FIG. 6C, slits SLT are formed in the slit trenches 133. The formation method of the slit SLT may be in accordance with the above-described embodiment method. The slit SLT is in contact with the conductive layers 158.

In some embodiments, referring to FIG. 2M and FIGS. 3 to 5, and 7, a thickness T1 of the conductive layer 103 is greater than a thickness T3 of the intermediate layer 106. Since the conductive layer 103 is replaced by the insulating liner layer 155 and the conductive layer 158, a thickness T2 of the conductive layer 158 is smaller than a thickness T1 of the conductive layer 103. Since the intermediate layers 106 is replaced by the gate layer 138, the tunneling layer 114, the charge storage layer 112 and the blocking layer 136, so a thickness T4 of the gate layer 138 is smaller than a thickness T3 of the intermediate layer 106. That is, T4<T3<T2<T1.

In other some embodiments, referring to FIGS. 6A to 6C, in order to remove the conductive layer 103 and the intermediate layer 106 in the array region R1, the staircase region and a portion of the peripheral region R2 at the same time, the thickness T1 of the conductive layer 103 is approximately equal to the thickness T3 of the intermediate layers 106. Thus, the thickness T2 of the conductive layer 158 is approximately equal to the thickness T4 of the gate layers 138. The thickness T1 is greater than the thickness T2, and the thickness T3 is greater than the thickness T4. That is, T1˜T3>T2˜T4.

The above embodiments are described with 3D AND flash memory. However, the embodiments of the present invention are not limited thereto, and the embodiments of the present invention can also be applied to 3D NOR flash memory or 3D NAND flash memory.

The embodiment of the present invention performs a replace process on a first conductive layer under the gate stack structure to form a second conductive layer, and disposing an insulating liner layer between a second conductive layer and the channel pillar can avoid short circuit between the second conductive layer and the channel pillar. By this method, the process window may be increased. Even if excessive lateral etching occurs when forming the hole for the conductive pillar (source/drain pillar), the subsequent formation of the conductive pillar (source/drain pillar)) will also not short-circuit with the second conductive layer.

What is claimed is:

1. A memory device comprising:
a stack structure located on a dielectric substrate, wherein the stack structure comprises a plurality of gate layers and a plurality of insulating layers alternately stacked with each other;
a channel pillar extending through the stack structure;
a first conductive pillar and a second conductive pillar located in the channel pillar and electrically connected to the channel pillar;
a charge storage structure located between the gate layers and the channel pillar;
a first conductive layer and a second conductive layer located between the dielectric substrate and the stack structure, wherein the second conductive is near the channel layer than the first conductive pillar; and
an insulating liner layer separating the second conductive layer from the channel pillar, and separating the second conductive layer from the first conductive layer.

2. The memory device according to claim 1, wherein the insulating liner layer surrounds the second conductive layer.

3. The memory device according to claim 1, wherein a material of the insulating liner layer is partially the same as a material of the charge storage structure.

4. The memory device according to claim 1, wherein materials of the insulating liner layer are the same as materials of the charge storage structure.

5. The memory device according to claim 1, wherein the insulating liner layer is a single layer.

6. The memory device according to claim 1, wherein the insulating liner layer is multiple layers.

7. The memory device according to claim 1, further comprising a slit extending through the stack structure and the second conductive layer.

8. The memory device according to claim 1, wherein the charge storage structure is further disposed between the slit and the second conductive layer.

9. The memory device according to claim 8, wherein the slit is in contact with the second conductive layer.

10. The memory device according to claim 1, wherein a material of the second conductive is the same as a material of the first conductive layer.

11. The memory device according to claim 10, wherein the first conductive layer and the second conductive comprises semiconductor.

12. The memory device according to claim 1, wherein a material of the second conductive is different from a material of the first conductive layer.

13. The memory device according to claim 1, wherein a material of the second conductive is the same as a material of the plurality of gate layers.

14. The memory device according to claim 13, wherein a material of the first conductive layer comprises semiconductor, and the material of the second conductive layer comprises a metal.

15. The memory device according to claim 13, wherein the stack structure over the first conductive layer comprises a material different from the plurality of gate layers of the gate stack structure over the second conductive.

16. The memory device according to claim 13, wherein the stack structure over the first conductive layer comprises a plurality of intermediate layers and the plurality of insulating layers alternately stacked with each other.

17. A method of fabricating a memory device, comprising:
forming a first conductive layer on a dielectric substrate
forming a stack structure on the first conductive layer, wherein the stack structure comprises a plurality of intermediate layers and a plurality of insulating layers stacked alternately with each other;
forming a channel pillar extending through the stack structure;
forming a first pillar and a second pillar in the channel pillar, wherein the first pillar and the second pillar are respectively electrically connected to a part of the channel pillar;
partially replacing the intermediate layers with a plurality of gate layers around the channel pillar;
forming a plurality of charge storage structures between the gate layers and the channel pillar;
partially replacing the first conductive layer around the channel pillar with a second conductive layer; and
forming an insulating liner between the second conductive layer and the channel pillar.

18. The method of fabricating a memory device according to claim 17, wherein the insulating liner layer is formed to surround the second conductive layer.

19. The method of fabricating a memory device according to claim 17, wherein materials of the insulating liner layer are the same as materials of the charge storage structure.

20. The method of fabricating a memory device according to claim 17, wherein partially replacing the first conductive layer around the channel pillar with a second conductive layer and forming the insulating liner layer comprise:
forming a slit trench through the stack structure and the first conductive layer;
removing the first conductive layer around the slit trench to form a horizontal opening;
forming the insulating liner layer on sidewalls of the horizontal opening; and
forming the second conductive layer in the horizontal opening.
